(19) United States
(12) Patent Application Publication
(10) Pub. No.: US 2026/0310249 A1
(43) Pub. Date: Oct. 8, 2026

(54) VOLTAGE CONTROL DEVICE AND OPERATION METHOD THEREOF

(71) Applicant: Wistron Corp., New Taipei City (TW)

(72) Inventors: Yu Jen CHIEN, New Taipei City (TW); Chu An KUO, New Taipei City (TW)

(21) Appl. No.: 19/245,733

(22) Filed: Jun. 23, 2025

(30) Foreign Application Priority Data
Apr. 7, 2025 (TW) 114112924

(51) Int. Cl. G05F 1/575

(52) U.S. Cl. CPC G05F 1/575

(57) ABSTRACT

The present invention provides a voltage control device and an operation method thereof. The voltage control method includes a control unit, a processing unit and a feedback sensing unit. The control unit generates a voltage step according to a requirement voltage and a feedback signal. The processing unit receives the voltage step, and generates a current signal according to the voltage step. The feedback sensing unit receives a voltage signal, and generates a feedback signal according to the voltage signal. The voltage signal is generated in response to the current signal.

### CROSS REFERENCE TO RELATED APPLICATIONS

This application claims priority of Taiwan Patent Application No. 114112924, filed on Apr. 7, 2025, the entirety of which is incorporated by reference herein.

### BACKGROUND OF THE INVENTION

### Field of the Invention

An embodiment of the present invention relates to a control device, and in particular it relates to a voltage control device and an operation method thereof.

### Description of the Related Art

Generally speaking, online games were constantly innovating during the e-sports stage of booming development. There are many gaming machines on the market, and it is necessary to ensure that the gaming experience is smooth and without lags. The specifications and requirements of computers have increased a lot, such as: CPU selection, graphics card, chassis, fan . . . etc. Memory overclocking is very common, and this function requires verification of the compatibility and stability of the motherboard and memory. During the extensive verification process of factory production, it was found that many machine problems pointed to memory overclocking.

However, when overclocking the memory, the voltage needs to be adjusted to meet the memory overclocking voltage control requirements, but the system may not know the voltage accuracy. If the actual voltage does not reach the expected voltage, this may lead to poor memory stability. Therefore, how to effectively generate a suitable voltage to increase the stability of memory operation has become one of the important problems to be solved.

### BRIEF SUMMARY OF THE INVENTION

An embodiment of the present invention provides a voltage control device and an operation method thereof, so that a suitable voltage may be effectively generated to increase the stability of memory operation, thereby increasing the convenience of use.

An embodiment of the present invention provides a voltage control device, which includes a control unit, a processing unit and a feedback sensing unit. The control unit is configured to generate a voltage step according to a requirement voltage and a feedback signal. The processing unit is configured to receive the voltage step, and generate a current signal according to the voltage step. The feedback sensing unit is configured to receive a voltage signal, and generate a feedback signal according to the voltage signal. The voltage signal is generated in response to the current signal.

In addition, an embodiment of the present invention provides an operation method of a voltage control device, which includes the following steps. A voltage step is generated through a control unit according to a requirement voltage and a feedback signal. The voltage step is received through a processing unit, and a current signal is generated according to the voltage step. A voltage signal is received through a feedback sensing unit, and a feedback signal is generated according to the voltage signal. The voltage signal is generated in response to the current signal.

According to the voltage control device and the operation method thereof disclosed by the embodiments of the present invention, the control unit generates the voltage step according to the requirement voltage and the feedback signal. The processing unit generates the current signal according to the voltage step. The feedback sensing unit generates the feedback signal according to the voltage signal, wherein the voltage signal is generated in response to the current signal. Therefore, a suitable voltage may be effectively generated to increase the stability of memory operation, thereby increasing the convenience of use.

### BRIEF DESCRIPTION OF THE DRAWINGS

The present invention can be more fully understood by reading the subsequent detailed description and examples with references made to the accompanying drawings, wherein:

FIG. 1 is a schematic view of a voltage control device according to an embodiment of the present invention;

FIG. 2 is a detailed schematic view of a voltage control device in FIG. 1;

FIG. 3 is a waveform diagram of a control signal, a working voltage provided to a memory inside a central processing unit and a working voltage of an internal signal provided by a voltage source module inside a memory according to an embodiment of the present invention;

FIG. 4 is a flowchart of an operation method of a voltage control device according to an embodiment of the present invention;

FIG. 5 is a detailed flowchart of step S402 in FIG. 4;

FIG. 6 is a detailed flowchart of step S506 in FIG. 5; and

FIG. 7 is a detailed flowchart of step S606 in FIG. 6.

### DETAILED DESCRIPTION OF THE INVENTION

The following description is of the contemplated mode of carrying out the present invention. This description is made for the purpose of illustrating the general principles of the present invention and should not be taken in a limiting sense. The scope of the present invention is determined by reference to the appended claims.

The present invention will be described with respect to particular embodiments and with reference to certain drawings, but the present invention is not limited thereto and is only limited by the claims. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Use of ordinal terms such as “first”, “second”, “third”, etc., in the claims to modify a claim component does not by itself connote any priority, precedence, or order of one claim component over another or the temporal order in which acts of a method are performed, but are used merely as labels to distinguish one claim component having a certain name from another component having the same name (but for use of the ordinal term) to distinguish the claim components.

In each of the following embodiments, the same reference number represents the same or similar element or component.

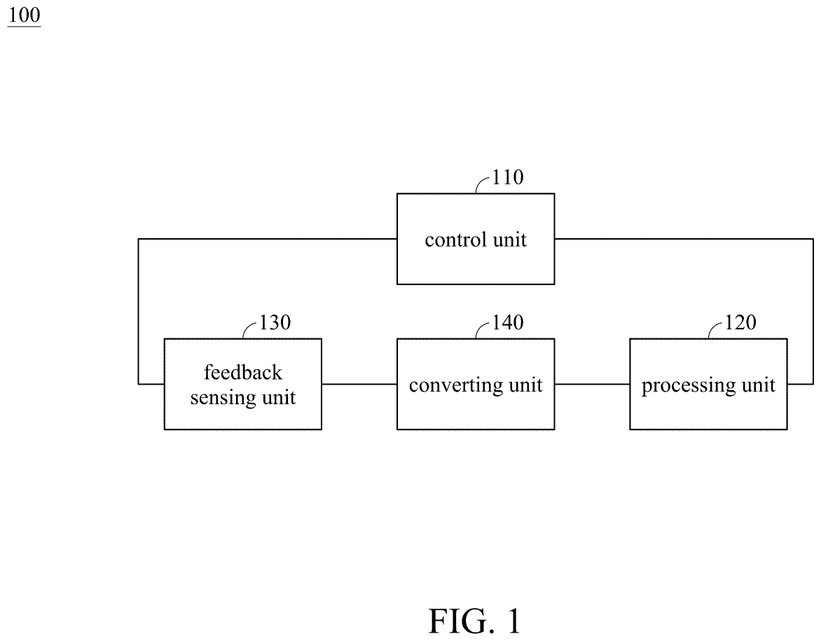

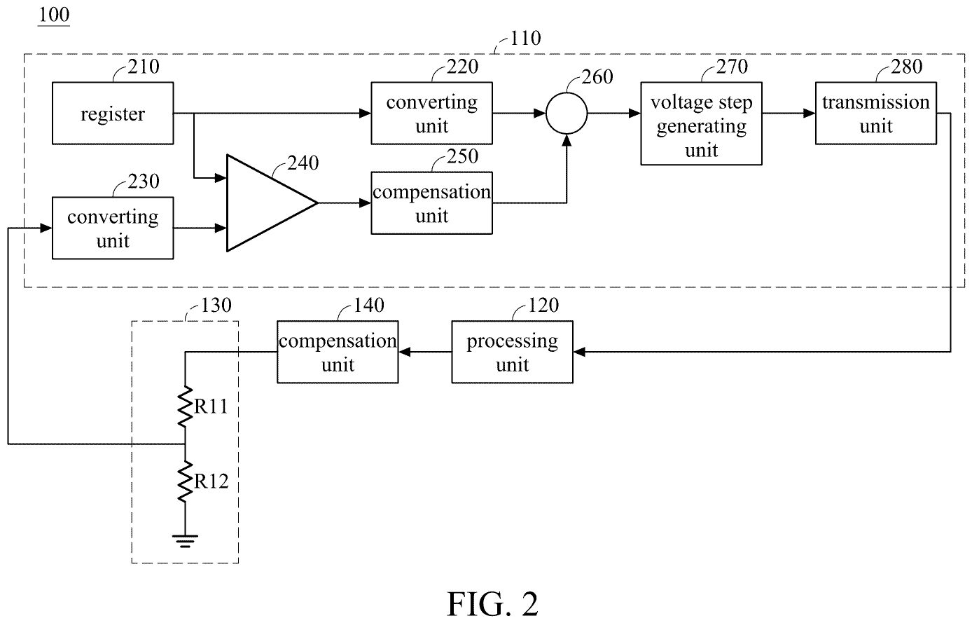

FIG. 1 is a schematic view of a voltage control device according to an embodiment of the present invention. FIG. 2 is a detailed schematic view of a voltage control device in FIG. 1. The voltage control device 100 of the embodiment is suitable for providing the working voltage required by the memory. Please refer to FIG. 1 and FIG. 2. The voltage control device 100 may include a control unit 110, a processing unit 120 and a feedback sensing unit 130.

The control unit 110 may generate a voltage step according to a requirement voltage and a feedback signal. In the embodiment, the control unit 110 may be an embedded controller (EC), but the embodiment of the present invention is not limited thereto.

In some embodiments, the control unit 110 may convert the requirement voltage to a predetermined voltage step. Then, the control unit 110 may compare the feedback signal with a predetermined voltage to generate a comparison signal. Afterward, the control unit 110 may generate a compensation voltage step according to the comparison signal and a predetermined value.

Furthermore, the control unit 110 may determine whether the comparison signal is consistent with the predetermined value. When the control unit 110 determines that the comparison signal is consistent with the predetermined value, in response to the control unit 110 determining that the comparison signal is consistent with the predetermined value, the control unit 110 keeps outputting the compensation voltage step. When the control unit 110 determines that the comparison signal is not consistent with the predetermined value, in response to the control unit 110 determining that the comparison signal is not consistent with the predetermined value, the control unit 110 may generate the compensation voltage step.

In addition, in some embodiments, when the control unit 110 determines that the comparison signal is not consistent with the predetermined value, in response to the control unit 110 determining that the comparison signal is not consistent with the predetermined value, the control unit 110 may determine whether the comparison signal is less than the predetermined value. When the control unit 110 determines that the comparison signal is less than the predetermined value, in response to the control unit 110 determining that the comparison signal is less than the predetermined value, the control unit 110 may generate a first voltage step as the compensation voltage step. When the control unit 110 determines that the comparison signal is not less than the predetermined value, in response to the control unit 110 determining that the comparison signal is not less than the predetermined value, the control unit 110 may generate a second voltage step as the compensation voltage step. In some embodiments, the above first voltage step may be different from the above second voltage step. Furthermore, the above first voltage step is, for example, a positive compensation voltage step, and the above second voltage step is, for example, a negative compensation voltage step.

In some embodiments, the compensation voltage step may be calculated by the following equation (1).

$${Step}_{Diff} = \frac{{V}_{out} - {V}_{in}}{5.6 mV} , \qquad ( 1 )$$

wherein Step_{Diff} is the compensation voltage step, Vₒᵤₜ is the requirement voltage, and Vᵢₙ is the voltage signal. In the embodiment, the voltage signal Vᵢₙ may be derived by the control unit 110 according to the feedback signal. For example, in some embodiments, assuming that the requirement voltage Vₒᵤₜ is 1.35V and the voltage signal Vᵢₙ is 1.32V, the control unit 110 may calculate that the compensation voltage step Step_{Diff} is approximately 5.35 (i.e., (1.35V-1.32V)/5.6 mV). Therefore, the control unit 110 may provide the compensation voltage step Step_{Diff} of +6 steps.

In some embodiments, assuming that the requirement voltage Vₒᵤₜ is 1.35V and the voltage signal Vᵢₙ is 1.38V, the control unit 110 may calculate that the compensation voltage step Step_{Diff} is approximately −5.35 (i.e., (1.35V-1.38V)/5.6 mV). Therefore, the control unit 110 may provide the compensation voltage step Step_{Diff} of −6 steps. The rest of compensation voltage steps Step_{Diff} may be deduced by analogy.

Then, the control unit 110 may calculate the predetermined voltage step and the compensation voltage step to generate a calculation result. For example, assuming that the predetermined voltage step is 48 steps and the compensation voltage step is +6 steps, the control unit 110 may perform an addition calculation on the predetermined voltage step of 48 steps and the compensation voltage step of +6 steps to generate the calculation result of 54 steps (i.e., 48+6). In addition, assuming that the predetermined voltage step is 48 steps and the compensation voltage step is-6 steps, the control unit 110 may perform an addition calculation on the predetermined voltage step of 48 steps and the compensation voltage step of −6 steps to generate the calculation result of 42 steps (i.e., 48+(−6)).

Afterward, the control unit 110 may generate the voltage step according to the calculation result. For example, when the calculation result is 54 steps, in response to the calculation result being 54 steps, the control unit 110 may generate the voltage step corresponding to the 54 steps. In addition, when the calculation result is 42 steps, in response to the calculation result being 42 steps, the control unit 110 may generate the voltage step corresponding to the 42 steps.

In some embodiments, the above requirement voltage and the above predetermined voltage may be set and stored through a basic input output system (BIOS). That is, the user may set the requirement voltage and the predetermined voltage through the basic input output system, and stores the requirement voltage and the predetermined voltage in the control unit 110.

In some embodiments, the control unit 110 may include a register 210, a converting unit 220, a converting unit 230, a comparison unit 240, a compensation unit 250, a calculation unit 260, a voltage step generating unit 270 and a transmission unit 280, as shown in FIG. 2.

The register 210 may store the requirement voltage and the predetermined voltage. That is, the user may set the requirement voltage and the predetermined voltage through the basic input output system, and stores the requirement voltage and the predetermined voltage in the register 210 of control unit 110. The converting unit 220 may be coupled to the register 210. The converting unit 220 may receive the requirement voltage, and may convert the requirement voltage to a predetermined voltage step. In the embodiment, the converting unit 220 may be a voltage-step converter, but the embodiment of the present invention is not limited thereto.

The converting unit 230 may be coupled to the feedback sensing unit 130. The converting unit 230 may receive the feedback signal, and may convert the feedback signal to a reference signal. In the embodiment, the converting unit 230 may be an analog-to-digital converter (A/D converter), but the embodiment of the present invention is not limited thereto.

The comparison unit 240 may be coupled to the register 210 and the converting unit 230. The comparison unit 240 may receive the reference signal and the predetermined voltage, and may compare the reference signal with the predetermined voltage to generate a comparison signal. In some embodiments, the comparison unit 240 may be a comparator or an operational amplifier, but the embodiment of the present invention is not limited thereto. The compensation unit 250 may be coupled to the comparison unit 240. The compensation unit 250 may receive the comparison signal, and may generate a compensation voltage step according to the comparison signal and a predetermined value.

The calculation unit 260 may be coupled to the converting unit 220 and the compensation unit 250. The calculation unit 260 may calculate the predetermined voltage step and the compensation voltage step to generate a calculation result. In some embodiments, the calculation unit 260 may be an adder, but the embodiment of the present invention is not limited thereto. That is, the calculation unit 260 may perform an additional calculation on the predetermined voltage step and the compensation voltage step to generate the calculation result.

The voltage step generating unit 270 may be coupled to the calculation unit 260. The voltage step generating unit 270 may receive the calculation result, and may generate the voltage step according to the calculation result. The transmission unit 280 may be coupled to the voltage step generating unit 270 and the processing unit 120. The transmission unit 280 may receive and transmit the voltage step, i.e., the transmission unit 280 may receive the voltage step generated by the voltage step generating unit 270, and may transmit the voltage step to the processing unit 120. In some embodiments, the transmission unit 280 may be an inter-integrated circuit (I2C) bus, but the embodiment of the present invention is not limited thereto.

The processing unit 120 may be coupled to the control unit 110. The processing unit 120 may receive the voltage step generated by the control unit 110, and may generate the current signal according to the above voltage step. In the embodiment, the processing unit 120 may be a micro control unit (MCU), a microprocessor, or another suitable processor, but the embodiment of the present invention is not limited thereto.

In some embodiments, the processing unit 120 may include a reference table, wherein the reference table has a corresponding relationship between the voltage step and a current, as shown in Table 1. Furthermore, the processing unit 120 may search the current corresponding to the voltage step according to the reference table to generate the current signal. In Table 1, the step of the voltage step is 128 steps, and the current corresponding to each step is 10 uA, but the embodiment of the present invention is not limited thereto.

For example, in some embodiments, when the voltage step received by the processing unit 120 is 48 steps, in response to the voltage step received by the processing unit 120 being 48 steps, the processing unit 120 may search that the current corresponding to the voltage step of 48 steps is 480 uA (i.e., 48*10 uA) in the reference table, and the processing unit 120 may use 480 uA as the current signal to generate the current signal with 480 uA. In some embodiments, when the voltage step received by the processing unit 120 is 54 steps, in response to the voltage step received by the processing unit 120 being 54 steps, the processing unit 120 may search that the current corresponding to the voltage step of 54 steps is 540 uA (i.e., 54*10 uA), and the processing unit 120 may use 540 uA as the current signal to generate the current signal with 540 uA. In some embodiments, when the voltage step received by the processing unit 120 is 42 steps, in response to the voltage step received by the processing unit 120 being 42 steps, the processing unit 120 may search that the current corresponding to the voltage step of 42 steps is 420 uA (i.e., 42*10 uA), and the processing unit 120 may use 420 uA as the current signal to generate the current signal with 420 uA. The rest of manners of the processing unit 120 generating the current signal may be deduced by analogy.

TABLE 1

| | | | current |
|---|---|---|---|
| step | bits [7:0] | address | (uA) |
| 0 | 10000000 | 80h | 0 |
| 1 | 10000001 | 81h | 10 |
| 2 | 10000010 | 82h | 20 |
| 3 | 10000011 | 83h | 30 |
| 4 | 10000100 | 84h | 40 |
| 5 | 10000101 | 85h | 50 |
| 6 | 10000110 | 86h | 60 |
| 7 | 10000111 | 87h | 70 |
| 8 | 10001000 | 88h | 80 |
| 9 | 10001001 | 89h | 90 |
| 10 | 10001010 | 8Ah | 100 |
| 11 | 10001011 | 8Bh | 110 |
| 12 | 10001100 | 8Ch | 120 |
| 13 | 10001101 | 8Dh | 130 |
| 14 | 10001110 | 8Eh | 1401 |
| 15 | 10001111 | 8Fh | 150 |
| 16 | 10010000 | 90h | 160 |
| 17 | 10010001 | 91h | 170 |
| 18 | 10010010 | 92h | 180 |
| 19 | 10010011 | 93h | 190 |
| 20 | 10010100 | 94h | 200 |
| 21 | 10010101 | 95h | 210 |
| 22 | 10010110 | 96h | 220 |
| 23 | 10010111 | 97h | 230 |
| 24 | 10011000 | 98h | 240 |
| 25 | 10011001 | 99h | 250 |
| 26 | 10011010 | 9Ah | 260 |
| 27 | 10011011 | 9Bh | 270 |
| 28 | 10011100 | 9Ch | 280 |
| 29 | 10011101 | 9Dh | 290 |
| 30 | 10011110 | 9Eh | 300 |
| 31 | 10011111 | 9Fh | 310 |
| 32 | 10100000 | A0h | 320 |
| 33 | 10100001 | A1h | 330 |
| 34 | 10100010 | A2h | 340 |
| 35 | 10100011 | A3h | 350 |
| 36 | 10100100 | A4h | 360 |
| 37 | 10100101 | A5h | 370 |
| 38 | 10100110 | A6h | 380 |
| 39 | 10100111 | A7h | 390 |
| 40 | 10101000 | A8h | 400 |
| 41 | 10101001 | A9h | 410 |
| 42 | 10101010 | AAh | 420 |
| 43 | 10101011 | ABh | 430 |
| 44 | 10101100 | ACh | 440 |
| 45 | 10101101 | ADh | 450 |
| 46 | 10101110 | AEh | 460 |
| 47 | 10101111 | AFh | 470 |
| 48 | 10110000 | B0h | 480 |
| 49 | 10110001 | B1h | 490 |
| 50 | 10110010 | B2h | 500 |
| 51 | 10110011 | B3h | 510 |
| 52 | 10110100 | B4h | 520 |
| 53 | 10110101 | B5h | 530 |
| 54 | 10110110 | B6h | 540 |
| 55 | 10110111 | B7h | 550 |
| 56 | 10111000 | B8h | 560 |
| 57 | 10111001 | B9h | 570 |
| 58 | 10111010 | BAh | 580 |
| 59 | 10111011 | BBh | 590 |
| 60 | 10111100 | BCh | 600 |
| 61 | 10111101 | BDh | 610 |
| 62 | 10111110 | BEh | 620 |
| 63 | 10111111 | BFh | 630 |
| 64 | 11000000 | C0h | 640 |
| 65 | 11000001 | C1h | 650 |
| 66 | 11000010 | C2h | 660 |
| 67 | 11000011 | C3h | 670 |
| 68 | 11000100 | C4h | 680 |
| 69 | 11000101 | C5h | 690 |
| 70 | 11000110 | C6h | 700 |
| 71 | 11000111 | C7h | 710 |
| 72 | 11001000 | C8h | 720 |
| 73 | 11001001 | C9h | 730 |
| 74 | 11001010 | CAh | 740 |
| 75 | 11001011 | CBh | 750 |
| 76 | 11001100 | CCh | 760 |
| 77 | 11001101 | CDh | 770 |
| 78 | 11001110 | CEh | 780 |
| 79 | 11001111 | CFh | 790 |
| 80 | 11010000 | D0h | 800 |
| 81 | 11010001 | D1h | 810 |
| 82 | 11010010 | D2h | 820 |
| 83 | 11010011 | D3h | 830 |
| 84 | 11010100 | D4h | 840 |
| 85 | 11010101 | D5h | 850 |
| 86 | 11010110 | D6h | 860 |
| 87 | 11010111 | D7h | 870 |
| 88 | 11011000 | D8h | 880 |
| 89 | 11011001 | D9h | 890 |
| 90 | 11011010 | DAh | 900 |
| 91 | 11011011 | DBh | 910 |
| 92 | 11011100 | DCh | 920 |
| 93 | 11011101 | DDh | 930 |
| 94 | 11011110 | DEh | 940 |
| 95 | 11011111 | DFh | 950 |
| 96 | 11100000 | E0h | 960 |
| 97 | 11100001 | E1h | 970 |
| 98 | 11100010 | E2h | 980 |
| 99 | 11100011 | E3h | 990 |
| 100 | 11100100 | E4h | 1000 |
| 101 | 11100101 | E5h | 1010 |
| 102 | 11100110 | E6h | 1020 |
| 103 | 11100111 | E7h | 1030 |
| 104 | 11101000 | E8h | 1040 |
| 105 | 11101001 | E9h | 1050 |
| 106 | 11101010 | EAh | 1060 |
| 107 | 11101011 | EBh | 1070 |
| 108 | 11101100 | ECh | 1080 |
| 109 | 11101101 | EDh | 1090 |
| 110 | 11101110 | EEh | 1100 |
| 111 | 11101111 | EFh | 1110 |
| 112 | 11110000 | F0h | 1120 |
| 113 | 11110001 | F1h | 1130 |
| 114 | 11110010 | F2h | 1140 |
| 115 | 11110011 | F3h | 1150 |
| 116 | 11110100 | F4h | 1160 |
| 117 | 11110101 | F5h | 1170 |
| 118 | 11110110 | F6h | 1180 |
| 119 | 11110111 | F7h | 1190 |
| 120 | 11111000 | F8h | 1200 |
| 121 | 11111001 | F9h | 1210 |
| 122 | 11111010 | FAh | 1220 |
| 123 | 11111011 | FBh | 1230 |
| 124 | 11111100 | FCh | 1240 |
| 125 | 11111101 | FDh | 1250 |
| 126 | 11111110 | FEh | 1260 |
| 127 | 11111111 | FFh | 1270 |

The feedback sensing unit 130 may receive a voltage signal, and generate a feedback signal according to the voltage signal, wherein the above voltage signal is generated in response to the current signal. In addition, the above voltage signal may be suitable for providing the working voltage required by the memory. In some embodiments, the feedback sensing unit 130 may perform a voltage division on the voltage signal to generate the feedback signal.

Furthermore, the feedback sensing unit 130 may include a first resistor R11 and a second resistor R12. The first resistor R11 includes a first terminal and a second terminal. The first terminal of the first resistor R11 may receive the voltage signal. The second terminal of the first resistor R11 is coupled to the control unit 110 and may generate the feedback signal. The second resistor R12 includes a first terminal and a second terminal. The first terminal of the second resistor R12 is coupled to the second terminal of the first resistor R11. The second terminal of the second resistor R12 is coupled to a ground terminal. In some embodiments, the resistance value of the first resistor R11 is the same as the resistance value of the second resistor R12, but the embodiment of the present invention is not limited thereto.

In some embodiments, the voltage control device 100 may further include a converting unit 140. The converting unit 140 may be coupled to the processing unit 120 and the feedback sensing unit 130. Furthermore, the converting unit 140 may be coupled to the processing unit 120 and the first terminal of the first resistor R11 of the feedback sensing unit 130. The converting unit 140 may receive the current signal, and may convert the current signal to the voltage signal. In some embodiments, the converting unit 140 may be a power converter or a voltage controller, but the embodiment of the present invention is not limited thereto.

In some embodiments, the converting unit 140 may convert the current signal to the voltage signal through the following equation (2).

$${V}_{out} = {V}_{ref} \times ( 1 + \frac{{R}_{1}}{{R}_{2}} ) + ( ( {Step}_{Default} \pm {Step}_{Diff} ) \times {I}_{each \_ step} ) \times {R}_{1} , \qquad ( 2 )$$

wherein Vₒᵤₜ is the voltage signal, Vref is a reference voltage, R₁ and R₂ are the internal resistances of the converting unit 140, I_{each_step} is the current corresponding to each voltage step, Step_{Default} is the predetermined voltage step, and Step_{Diff} is the compensation voltage step.

In an entire operation of the voltage control device 100, the use may set the requirement voltage and the predetermined voltage through the basic input output system, and may store the requirement voltage and the predetermined voltage in the control unit 110 (the register 210). Assuming that the requirement voltage is 1.35V, and the predetermined voltage is, for example, 0.675V. The control unit 110 (the converting unit 220) converts the requirement voltage (such as 1.35V) to the predetermined voltage step (such as 48 steps). At this time, the control unit 110 (the converting unit 230) has not received the feedback signal yet, so the control unit 110 (the compensation unit 250) may not generate the compensation voltage step. Then, the control unit 110 (the calculation unit 260) may generate the calculation result of 48 steps. Afterward, the control unit 110 (the voltage step generating unit 270) may generate the voltage step corresponding to the 48 steps, and may transmit the voltage step of the 48 steps to the processing unit 120.

Then, the processing unit 120 may search that the current corresponding the voltage step of 48 steps is 480 uA (i.e., 48*10 uA) in the reference table according to the voltage step of 48 steps, and the processing unit 120 may use 480 uA as the current signal to generate the current signal with 480 uA. Afterward, the converting unit 140 may generate the corresponding voltage signal (such as 1.35V) according to the current signal with 480 uA and equation (2).

Then, the feedback sensing unit 130 performs the voltage division on the voltage signal to generate the feedback signal. At this time, since the voltage signal is limited by the circuit board process or the error of the electrical component (such as 0.03V), the voltage signal is 1.32V (such as 1.35V-0.03V), and the feedback sensing unit 130 may generate the feedback signal with 0.66V. Afterward, the control unit 110 (the converting unit 230) converts the feedback signal to the reference signal. Then, the control unit 110 (the comparison unit 240) compares the reference signal (the feedback signal) with the predetermined voltage to generate the comparison signal, such as 0.15V (i.e., 0.675-0.66V). Afterward, the control unit 110 (the compensation unit 250) may determine whether the comparison signal (such as 0.15V) is consistent with the predetermined value (such as 0.02V, about 0V). When the control unit 110 (the compensation unit 250) determines that the comparison signal (such as 0.15V) is not consistent with the predetermined value (such as 0.02V, about 0V), in response to the control unit 110 (the compensation unit 250) determining that the comparison signal (such as 0.15V) is not consistent with the predetermined value (such as 0.02V, about 0V), the control unit 110 (the compensation unit 250) may determine whether the comparison signal (such as 0.15V) is less than the predetermined value (such as 0.02V, about 0V).

When the control unit 110 (the compensation unit 250) determines that the comparison signal (such as 0.15V) is not less than the predetermined value (such as 0.02V, about 0V), in response to the control unit 110 (the compensation unit 250) determining that the comparison signal (such as 0.15V) is not less than the predetermined value (such as 0.02V, about 0V), the control unit 110 (the compensation unit 250) may generate, for example, the second voltage step of +6 steps as the compensation voltage step through equation (1), i.e., the compensation voltage step is +6 steps. Then, the control unit 110 (the calculation unit 260) may perform an addition calculation on the predetermined voltage step of 48 steps and the compensation voltage step of +6 steps to generate the calculation result of 54 steps (i.e., 48+6). Afterward, the control unit 110 (the voltage step generating unit 270) may generate the voltage step corresponding to the 54 steps, and transmit the voltage step of 54 steps to the processing unit 120.

Then, the processing unit 120 may search that the current corresponding the voltage step of 54 steps is 540 uA (i.e., 54*10 uA) in the reference table according to the voltage step of 54 steps, and the processing unit 120 may use 540 uA as the current signal to generate the current signal with 540 uA. Afterward, the converting unit 140 may generate the corresponding voltage signal (such as 1.38V) according to the current signal with 540 uA and equation (2).

Then, the feedback sensing unit 130 performs the voltage division on the voltage signal to generate the feedback signal. At this time, since the voltage signal is limited by the circuit board process or the error of the electrical component (such as 0.03V), the voltage signal is 1.35V (such as 1.38V-0.03V), and the feedback sensing unit 130 may generate the feedback signal with 0.675V. Afterward, the control unit 110 (the converting unit 230) converts the feedback signal to the reference signal. Then, the control unit 110 (the comparison unit 240) compares the reference signal (the feedback signal) with the predetermined voltage to generate the comparison signal, such as 0V (i.e., 0.675-0.675V). Afterward, the control unit 110 (the compensation unit 250) may determine whether the comparison signal (such as 0V) is consistent with the predetermined value (such as 0.02V, about 0V). When the control unit 110 (the compensation unit 250) determines that the comparison signal (such as 0V) is consistent with the predetermined value (such as 0.02V, about 0V), in response to the control unit 110 (the compensation unit 250) determining that the comparison signal (such as 0V) is not consistent with the predetermined value (such as 0.02V, about 0V), the control unit 110 (the compensation unit 250) may keep outputting the compensation voltage step of +6 steps, so that the control unit 110 continuously outputs the voltage step of 54, and the converting unit 140 may continuously provide the accurate voltage signal to memory, thereby increasing the stability of the memory.

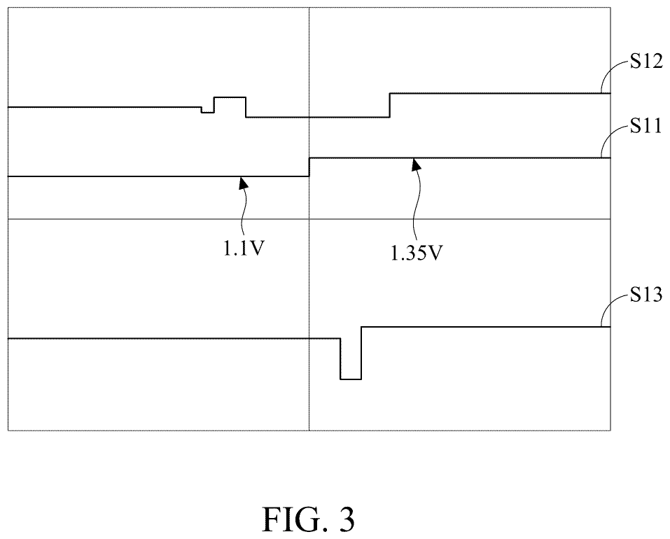

FIG. 3 is a waveform diagram of a control signal, a working voltage provided to a memory inside a central processing unit and a working voltage of an internal signal provided by a voltage source module inside a memory according to an embodiment of the present invention. In FIG. 3, the reference number S11 is the voltage signal (suitable for providing the working voltage required by the memory), the reference number S12 is the working voltage provided to the memory inside the central processing unit, and the reference number S13 is the working voltage of an internal signal provided by a voltage source module inside the memory. As can be seen from FIG. 3, through the voltage control device 100 of the embodiment, the voltage signal S11 may be adjusted from 1.1V to 1.35V, so as to provide the accurate voltage signal S11 (such as 1.35V) to the memory, thereby increasing the stability of the memory.

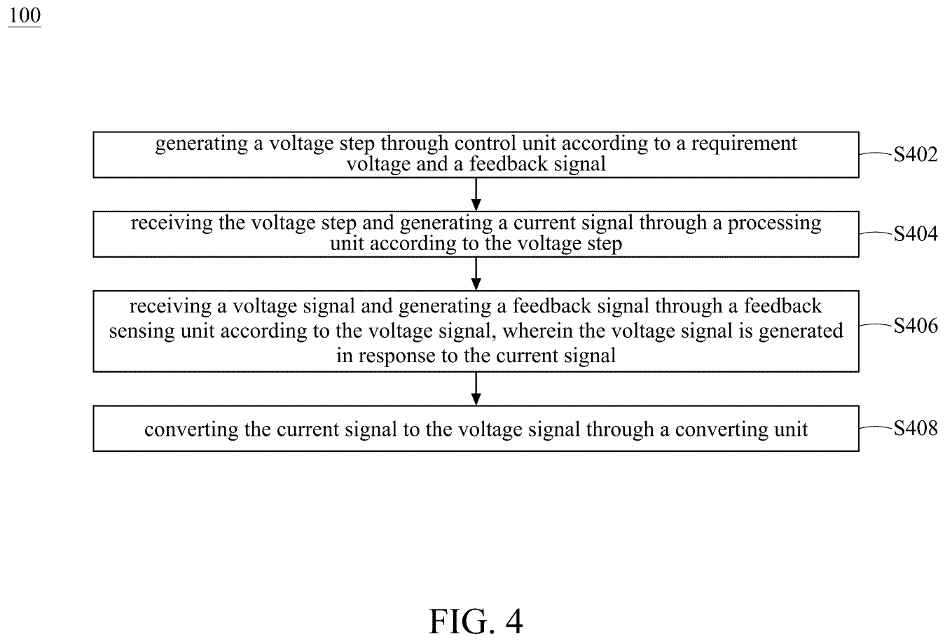

FIG. 4 is a flowchart of an operation method of a voltage control device according to an embodiment of the present invention. In step S402, the method involves generating a voltage step through control unit according to a requirement voltage and a feedback signal. In step S404, the method involves receiving the voltage step and generating a current signal through a processing unit according to the voltage step. In step S406, the method involves receiving a voltage signal and generating a feedback signal through a feedback sensing unit according to the voltage signal, wherein the voltage signal is generated in response to the current signal. In step S408, the method involves converting the current signal to the voltage signal through a converting unit.

In some embodiments, the processing unit may include a reference table, wherein the reference table has a corresponding relationship between the voltage step and a current. In addition, in some embodiments, step S404 may include searching the current corresponding to the voltage step through the processing unit according to the reference table to generate the current signal. Furthermore, step S406 may include receiving the voltage signal through the feedback sensing unit and performing a voltage division on the voltage signal to generate the feedback signal.

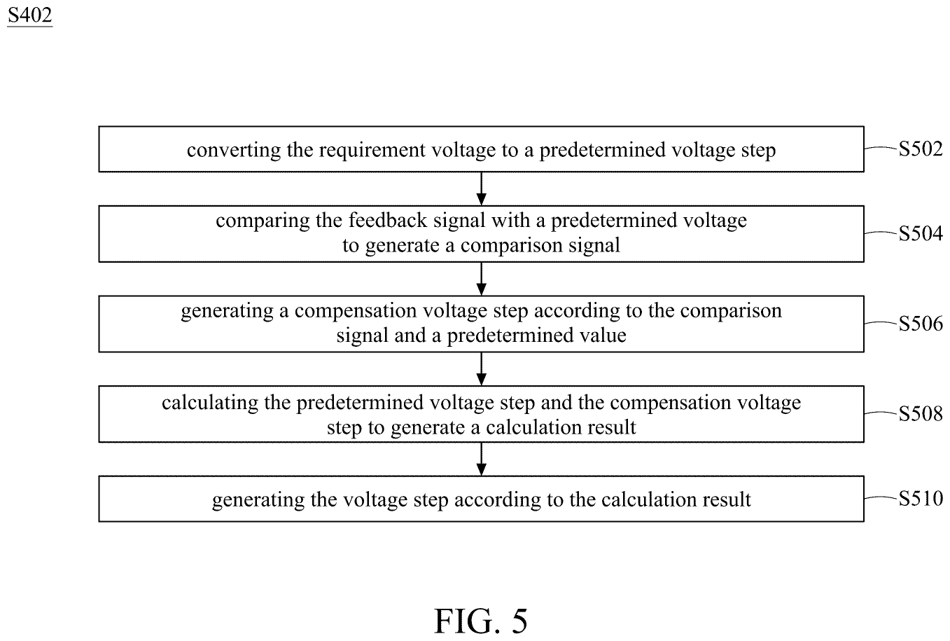

FIG. 5 is a detailed flowchart of step S402 in FIG. 4. In step S502, the method involves converting the requirement voltage to a predetermined voltage step. In step S504, the method involves comparing the feedback signal with a predetermined voltage to generate a comparison signal. In step S506, the method involves generating a compensation voltage step according to the comparison signal and a predetermined value. In step S508, the method involves calculating the predetermined voltage step and the compensation voltage step to generate a calculation result. In step S510, the method involves generating the voltage step according to the calculation result. In some embodiments, the above requirement voltage and the above predetermined voltage are set and stored, for example, through a basic input output system.

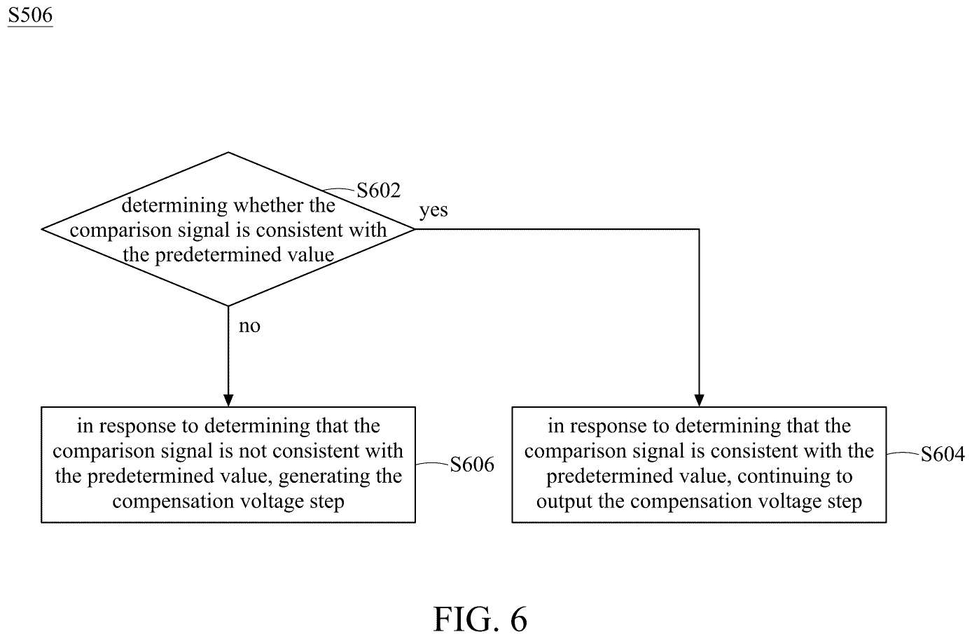

FIG. 6 is a detailed flowchart of step S506 in FIG. 5. In step S602, the method involves determining whether the comparison signal is consistent with the predetermined value. When determining that the comparison signal is consistent with the predetermined value, the method performs step S604. In step S604, the method involves in response to determining that the comparison signal is consistent with the predetermined value, continuing to output the compensation voltage step. When determining that the comparison signal is not consistent with the predetermined value, the method performs step S606. In step S606, the method involves in response to determining that the comparison signal is not consistent with the predetermined value, generating the compensation voltage step.

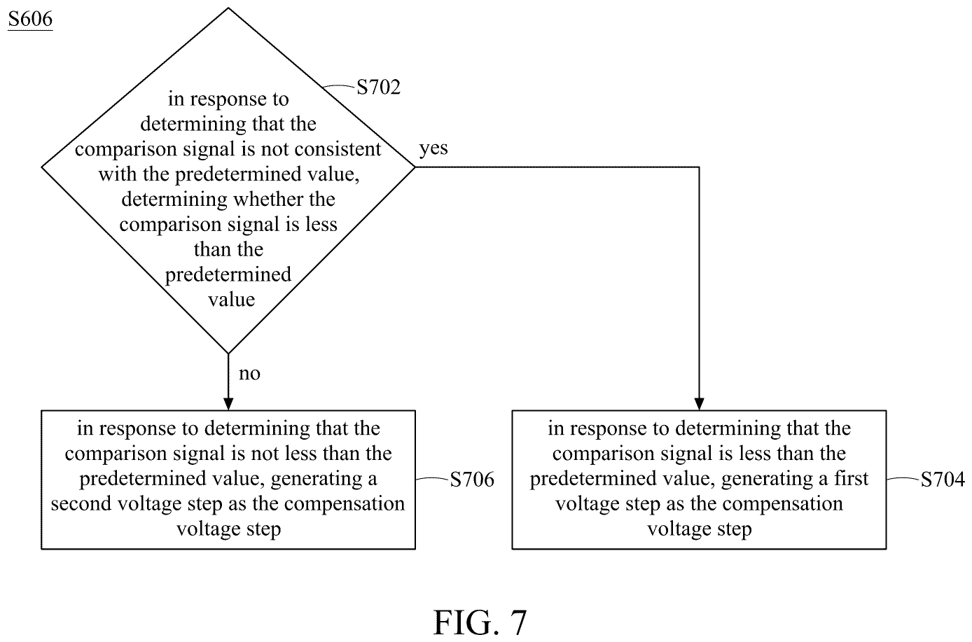

FIG. 7 is a detailed flowchart of step S606 in FIG. 6. In step S702, the method involves in response to determining that the comparison signal is not consistent with the predetermined value, determining whether the comparison signal is less than the predetermined value. When determining that the comparison signal is less than the predetermined value, the method performs step S704. In step S704, the method involves in response to determining that the comparison signal is less than the predetermined value, generating a first voltage step as the compensation voltage step. When determining that the comparison signal is not less than the predetermined value, the method performs step S706. In step S706, the method involves in response to determining that the comparison signal is not less than the predetermined value, generating a second voltage step as the compensation voltage step.

It should be noted that the order of the steps of FIG. 4, FIG. 5, FIG. 6 and FIG. 7 is only for illustrative purposes, and is not intended to limit the order of the steps of the present invention. The user may change the order of the steps above to meet specific requirements. The flowcharts described above may add additional steps or use fewer steps without departing from the spirit and scope of the present invention.

In summary, according to the voltage control device and the operation method thereof disclosed by the embodiments of the present invention, the control unit generates the voltage step according to the requirement voltage and the feedback signal. The processing unit generates the current signal according to the voltage step. The feedback sensing unit generates the feedback signal according to the voltage signal, wherein the voltage signal is generated in response to the current signal. Therefore, a suitable voltage may be effectively generated to increase the stability of memory operation, thereby increasing the convenience of use.

While the present invention has been described by way of example and in terms of the preferred embodiments, it should be understood that the present invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A voltage control device, comprising:
a control unit, configured to generate a voltage step according to a requirement voltage and a feedback signal;
a processing unit, configured to receive the voltage step and generate a current signal according to the voltage step;
a feedback sensing unit, configured to receive a voltage signal and generate a feedback signal according to the voltage signal, wherein the voltage signal is generated in response to the current signal.

2. The voltage control device as claimed in claim 1, wherein the control unit is configured to convert the requirement voltage to a predetermined voltage step, compare the feedback signal with a predetermined voltage to generate a comparison signal, generate a compensation voltage step according to the comparison signal and a predetermined value, calculate the predetermined voltage step and the compensation voltage step to generate a calculation result, and generate the voltage step according to the calculation result.

3. The voltage control device as claimed in claim 2, wherein the control unit is configured to determine whether the comparison signal is consistent with the predetermined value, in response to the control unit determining that the comparison signal is consistent with the predetermined value, the control unit is configured to keep outputting the compensation voltage step, and in response to the control unit determining that the comparison signal is not consistent with the predetermined value, the control unit is configured to generate the compensation voltage step.

4. The voltage control device as claimed in claim 3, wherein in response to the control unit determining that the comparison signal is not consistent with the predetermined value, the control unit is configured to determine whether the comparison signal is less than the predetermined value, in response to the control unit determining that the comparison signal is less than the predetermined value, the control unit is configured to generate a first voltage step as the compensation voltage step, and in response to the control unit determining that the comparison signal is not less than the predetermined value, the control unit is configured to generate a second voltage step as the compensation voltage step.

5. The voltage control device as claimed in claim 2, wherein the requirement voltage and the predetermined voltage are set and stored through a basic input output system.

6. The voltage control device as claimed in claim 1, wherein the control unit comprises:
a register, configured to store the requirement voltage and a predetermined voltage;
a first converting unit, configured to receive the requirement voltage and convert the requirement voltage to a predetermined voltage step;
a second converting unit, configured to receive the feedback signal and convert the feedback signal to a reference signal;
a comparison unit, configured to receive the reference signal and the predetermined voltage and compare the reference signal with the predetermined voltage to generate a comparison signal;
a compensation unit, configured to receive the comparison signal and generate a compensation voltage step according to the comparison signal and a predetermined value;
a calculation unit, configured to calculate the predetermined voltage step and the compensation voltage step to generate a calculation result;
a voltage step generating unit, configured to receive the calculation result and generate the voltage step according to the calculation result; and
a transmission unit, configured to receive and transmit the voltage step.

7. The voltage control device as claimed in claim 1, wherein the processing unit comprises a reference table, wherein the reference table has a corresponding relationship between the voltage step and a current.

8. The voltage control device as claimed in claim 7, wherein the processing unit is configured to search the current corresponding to the voltage step according to the reference table to generate the current signal.

9. The voltage control device as claimed in claim 1, wherein the feedback sensing unit is configured to perform a voltage division on the voltage signal to generate the feedback signal.

10. The voltage control device as claimed in claim 9, wherein the feedback sensing unit comprises:
a first resistor, comprising a first terminal and a second terminal, wherein the first terminal of the first resistor is configured to receive the voltage signal, and the second terminal of the first resistor is coupled to the control unit and configured to generate the feedback signal; and
a second resistor, comprising a first terminal and a second terminal, wherein the first terminal of the second resistor is coupled to the second terminal of the first resistor, and the second terminal of the second resistor is coupled to a ground terminal.

11. The voltage control device as claimed in claim 1, further comprising:
a converting unit, configured to convert the current signal to the voltage signal.

12. An operation method of a voltage control device, comprising:
generating, through a control unit, a voltage step according to a requirement voltage and a feedback signal;
receiving, through a processing unit, the voltage step and generating a current signal according to the voltage step; and
receiving, through a feedback sensing unit, a voltage signal and generating a feedback signal according to the voltage signal, wherein the voltage signal is generated in response to the current signal.

13. The operation method of the voltage control device as claimed in claim 12,
wherein the step of generating, through the control unit, the voltage step according to the requirement voltage and the feedback signal comprises:
converting the requirement voltage to a predetermined voltage step;
comparing the feedback signal with a predetermined voltage to generate a comparison signal;
generating a compensation voltage step according to the comparison signal and a predetermined value;
calculating the predetermined voltage step and the compensation voltage step to generate a calculation result; and
generating the voltage step according to the calculation result.

14. The operation method of the voltage control device as claimed in claim 13,
wherein the step of generating the compensation voltage step according to the comparison signal and the predetermined value comprises:
determining whether the comparison signal is consistent with the predetermined value;
in response to determining that the comparison signal is consistent with the predetermined value, continuing to output the compensation voltage step; and
in response to determining that the comparison signal is not consistent with the predetermined value, generating the compensation voltage step.

15. The operation method of the voltage control device as claimed in claim 14, wherein the step of in response to determining that the comparison signal is not consistent with the predetermined value, generating the compensation voltage step comprises:
in response to determining that the comparison signal is not consistent with the predetermined value, determining whether the comparison signal is less than the predetermined value;
in response to determining that the comparison signal is less than the predetermined value, generating a first voltage step as the compensation voltage step; and
in response to determining that the comparison signal is not less than the predetermined value, generating a second voltage step as the compensation voltage step.

16. The operation method of the voltage control device as claimed in claim 13, wherein the requirement voltage and the predetermined voltage are set and stored through a basic input output system.

17. The operation method of the voltage control device as claimed in claim 12, wherein the processing unit comprises a reference table, wherein the reference table has a corresponding relationship between the voltage step and a current.

18. The operation method of the voltage control device as claimed in claim 17, wherein receiving, through a processing unit, the voltage step and generating the current signal according to the voltage step comprises:
searching, through the processing unit, the current corresponding to the voltage step according to the reference table to generate the current signal.

19. The operation method of the voltage control device as claimed in claim 12, wherein the step of receiving, through the feedback sensing unit, the voltage signal and generating the feedback signal according to the voltage signal comprises:
receiving, through the feedback sensing unit, the voltage signal and performing a voltage division on the voltage signal to generate the feedback signal.

20. The operation method of the voltage control device as claimed in claim 12, further comprising:
converting, through a converting unit, the current signal to the voltage signal.
